(19) United States
(12) Patent Application Publication
(10) Pub. No.: US 2024/0357937 A1
(43) Pub. Date: Oct. 24, 2024

(54) METHOD FOR TRANSFERRING A USEFUL LAYER TO A FRONT FACE OF CARRIER SUBSTRATE

(71) Applicant: Soitec, BERNIN (FR)

(72) Inventors: Cédric Charles-Alfred, BERNIN (FR); Nadia Ben Mohamed, BERNIN (FR)

(21) Appl. No.: 18/685,991

(22) PCT Filed: Aug. 17, 2022
(86) PCT No.: PCT/EP2022/073007

§ 371 Date: Feb. 23, 2024

(30) Foreign Application Priority Data
Sep. 6, 2021 (FR) FR2109287

(51) Int. Cl. H10N 30/072; H10N 30/853

(52) U.S. Cl. CPC H10N 30/072; H10N 30/8536; H10N 30/8542; H10N 30/8548; H10N 30/8554

(57) ABSTRACT

A method for transferring a useful layer to a carrier substrate comprises: a) providing a donor substrate including a donor layer; b) forming an embrittlement area by implanting species in the donor layer and defining therewith a useful layer; c) assembling the carrier substrate with the donor substrate; d) a heat treatment step including a first phase and a second phase, wherein the first phase, having a first duration, is heated to a first temperature and is suitable for maturing defects and preventing a fracture from occurring in the embrittlement area, and wherein the second phase, having a second duration, comprises a bearing at a second temperature, below the first temperature, and is suitable for causing a fracture to occur along the embrittlement area.

### CROSS-REFERENCE TO RELATED APPLICATIONS

This application is a national phase entry under 35 U.S.C. § 371 of International Patent Application PCT/EP2022/073007, filed Aug. 17, 2022, designating the United States of America and published as International Patent Publication WO 2023/030896 A1 on Mar. 9, 2023, which claims the benefit under Article 8 of the Patent Cooperation Treaty of French Patent Application Serial No. FR2109287, filed Sep. 6, 2021.

### TECHNICAL FIELD

The present disclosure relates to the field of heterogeneous structures.

In particular, the present disclosure relates to a process for transferring a working layer to a support substrate involving SmartCut™ technology.

More particularly, the process according to the present disclosure relates to a process with which it is possible to decrease the fracture temperature in order to reduce the risk of development of cracks and/or of delamination.

The process according to the present disclosure is then advantageously implemented for the production of a piezoelectric-on-insulator substrate.

### BACKGROUND

Document FR3068508A1 discloses a process for transferring a working layer to a support substrate. In particular, document FR3068508A1 discloses a process for the transfer, according to a SmartCut™ process, of a working layer to a support substrate.

The transfer process described in document FR3068508A1 comprises in this connection the following steps:
a0) a step of providing a donor substrate that comprises, from a front face to a rear face, a donor layer lying on one face of a handle substrate;
b0) a step of implanting of species, via the front face, in the donor layer in such a way as to form a weakened zone that extends along a plane parallel to the front face and that, with said front face, delimits a working layer;
c0) a step of joining the front face of the donor substrate with a main face of a support substrate; and
d0) a step of subjecting to a heat treatment intended to initiate the propagation of a fracture wave within the weakened zone and then to transfer the working layer to the main face of the support substrate.

This process is implemented advantageously provided the materials forming the working layer and the support substrate have different coefficients of thermal expansion. More specifically, the process disclosed in document FR3068508A1, aimed at reducing the risk of uncontrolled fracture or of partial transfer or defectiveness of the working layer, proposes the use of a handle substrate made of a material having a coefficient of thermal expansion similar to that of the material forming the support substrate.

Nevertheless, the use of a donor substrate of this kind remains problematic.

This is because the interface formed between the donor layer and the handle substrate is sensitive to the heat treatment. More particularly, this interface can be the site of development of cracks and/or of delamination of the donor layer.

An object of the present disclosure is thus to propose a process for transferring a working layer to a donor substrate that is able to prevent the development of cracks at the interface formed between the donor layer and the handle substrate and of delamination of the donor layer.

### BRIEF SUMMARY

The object of the present disclosure is achieved by a process for transferring a working layer onto a support substrate, the process comprising the following steps:
a) providing a donor substrate that comprises, starting from a main face, a donor layer formed from a piezoelectric material and a handle substrate, the donor layer lying on one face of the handle substrate;
b) forming of a weakened zone, through the implantation of species in the donor layer, that is parallel to the main face and that, with the latter, delimits a working layer;
c) joining the support substrate with the donor substrate in such a way as to interpose the donor layer between the handle substrate and the support substrate;
d) subjecting to a heat treatment that comprises, in this order, a first phase and a second phase; the first phase, of a first duration, comprises an increase in temperature to a first temperature and is designed firstly to allow a maturation of defects, generated by the species, in the weakened zone and secondly to prevent initiation of a fracture in said weakened zone; the second phase, of a second duration, comprises a hold period at a second temperature lower than the first temperature and is designed to initiate a fracture along the weakened zone and thus to transfer the working layer to the front face, and
wherein an absolute difference between the first temperature and the second temperature is less than 40° C. and greater than 30° C.

In one embodiment, step d) also comprises a strengthening phase preceding the first phase and performed at a temperature, termed the strengthening temperature, lower than the first temperature, the strengthening phase being intended to strengthen a bonding energy of an interface formed between the support substrate and the donor substrate during the performance of step c).

In one embodiment, the first phase comprises, in this order: an increase in temperature, a hold period at the first temperature, and a decrease in temperature to the second temperature.

In one embodiment, the first phase is adjusted according to the conditions of implantation of the species during the performance of step b).

In one embodiment, the relative difference between the coefficients of thermal expansion of the materials forming respectively the handle substrate and the support substrate is less than 10%.

In one embodiment, the handle substrate comprises a bulk substrate on one face of which lies an intermediate layer, the intermediate layer being interposed between the donor layer and the bulk substrate; advantageously, the intermediate layer comprises a polymeric material.

In one embodiment, the first temperature is less than 300° C., advantageously less than 250° C., even more advantageously less than 220° C.

In one embodiment, the absolute difference between the first temperature and the second temperature is less than 40° C. and greater than 30° C.

In one embodiment, the second duration is less than 6 hours, advantageously less than 4 hours.

In one embodiment, the second temperature is less than 180° C., advantageously less than 170° C.

In one embodiment, the species comprise at least one element selected from: hydrogen ions, helium ions.

In one embodiment, the piezoelectric material comprises at least one element selected from: LiTaO₃, LiNbO₃, LiAlO₃, BaTiO₃, PbZrTiO₃, KNbO₃, BaZrO₃, CaTiO₃, PbTiO₃, KTaO₃.

In one embodiment, step c) of joining is preceded by a step of forming of a layer of dielectric material on the donor layer and/or on a front face of the support substrate.

In one embodiment, step c) of joining comprises a molecular bonding.

### BRIEF DESCRIPTION OF THE DRAWINGS

Other features and advantages will become apparent in the following description of a process for transferring a working layer onto a support substrate according to the present disclosure, which are given by way of nonlimiting examples with reference to the accompanying figures in which:

FIG. 1A is a schematic representation of step a) of the process according to the present disclosure; more particularly, FIG. 1A shows the donor substrate along a sectional plane perpendicular to a main face of said donor substrate;

FIG. 1B is a schematic representation of step b) of the process according to the present disclosure; more particularly, FIG. 1B shows the donor substrate along a sectional plane perpendicular to a main face of said donor substrate and the arrows signify the implantation of species via the main face so as to form the weakened zone;

FIG. 1C is a schematic representation of step c) of the process according to the present disclosure; more particularly, FIG. 1C shows an assembly formed by the donor substrate and the support substrate along a sectional plane perpendicular to the main face of said donor substrate;

FIG. 1D is a schematic representation of the first phase of step d) of the process according to the present disclosure; more particularly, FIG. 1D shows the maturation of the defects in the weakened zone of the assembly formed by the donor substrate and the support substrate along a sectional plane perpendicular to the main face of said donor substrate;

FIG. 1E is a schematic representation of the second phase of step d) of the process according to the present disclosure; more particularly, FIG. 1E shows the fracture resulting in detachment of the working layer from the donor layer for the purpose of transferring it onto the front face of the support substrate;

FIG. 2 is a schematic representation of the donor substrate along a sectional plane perpendicular to a main face of said donor substrate and according to one particular embodiment of the present disclosure; more particularly, according to this embodiment, the handle substrate comprises a bulk substrate on one face of which lies an intermediate layer such that said intermediate layer is interposed between the bulk substrate and the donor layer;

FIG. 3 is a graphical representation of a heat treatment likely to be implemented in the context of the present disclosure; more particularly, the horizontal axis shows the time t in hours and the vertical axis shows the temperature T° in degrees Celsius;

FIG. 4A is a graphical representation of a heat treatment, termed first treatment, likely to be implemented for the determination of parameters relating to the performance of step d); more particularly, the horizontal axis shows the time in hours and the vertical axis shows the temperature in degrees Celsius;

FIG. 4B is a graphical representation of a heat treatment, termed second treatment, likely to be implemented for the determination of parameters relating to the performance of step d); more particularly, the horizontal axis shows the time in hours and the vertical axis shows the temperature in degrees Celsius;

FIG. 4C is a graphical representation of a heat treatment, termed third treatment, likely to be implemented for the determination of parameters relating to the performance of step d); more particularly, the horizontal axis shows the time in hours and the vertical axis shows the temperature in degrees Celsius;

FIG. 5 depicts a donor substrate that comprises a layer of dielectric material, termed first layer, lying on the donor layer; and

FIG. 6 depicts a support substrate that comprises a layer of dielectric material (for example, of silica), termed second layer, lying on the front face of the support substrate.

### DETAILED DESCRIPTION

For the sake of simplicity in the description that follows, the same references are used for identical elements or for elements performing the same function in the prior art or in the various presented embodiments of the process.

The figures are schematic representations, which, for the sake of legibility, are not to scale. In particular, the thicknesses of the layers are not to scale with respect to the lateral dimensions of these layers.

The present disclosure relates to a process for transferring a working layer onto a front face of a support substrate.

In particular, the process comprises the performance of steps a) to d). More particularly, step a) comprises the providing of a donor substrate. The latter is provided with, starting from a main face, a donor layer formed from a piezoelectric material and a handle substrate.

Step b) comprises the forming, through the implantation of species, in the donor layer, of a weakened zone that extends in parallel to the main face and that, with the latter, delimits a working layer.

Step c) comprises the joining of the donor layer with a front face of a support substrate.

Step d) comprises a heat treatment that comprises, in this order, a first phase and a second phase. The first phase of a first duration comprises an increase in temperature to a first temperature and is designed first, to initiate a maturation of defects generated by the species in the weakened zone and, second, to prevent initiation of a fracture in the weakened zone. The second phase comprises a hold period at a second temperature lower than the first temperature and is of a second duration so as to initiate a fracture along the weakened zone and thus to transfer the working layer onto the front face.

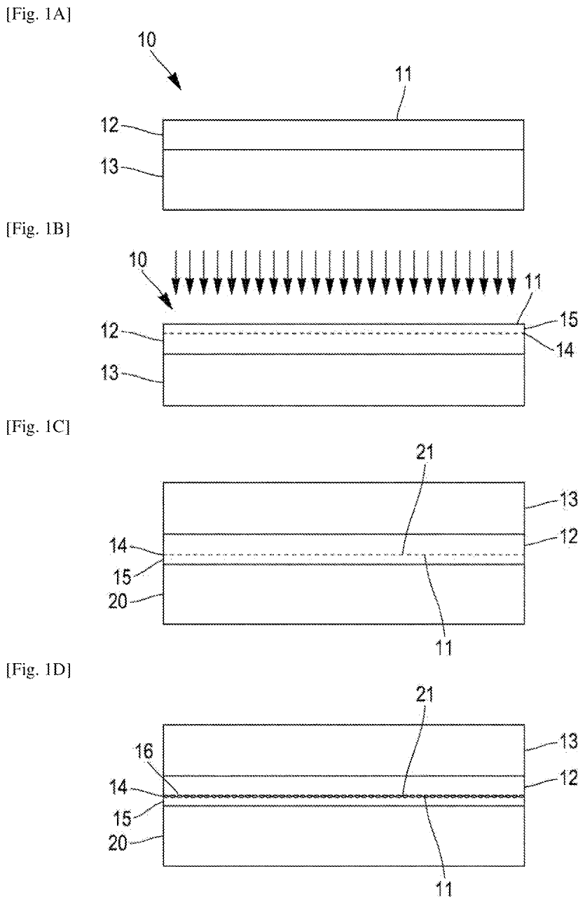

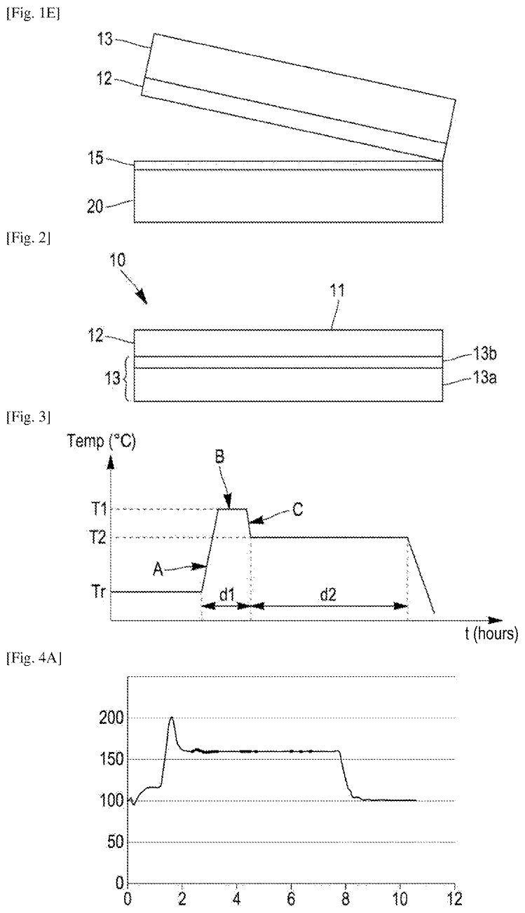

FIGS. 1A to 1E are schematic representations of the various steps implemented in the process for transferring a working layer onto the front face of a support substrate according to the present disclosure.

FIG. 1A is a depiction of a step a) that comprises the providing of a donor substrate 10. In this connection, the donor substrate 10 comprises, starting from a main face 11, a donor layer 12 formed from a piezoelectric material and a handle substrate 13. In other words, the donor layer 12 lies on one face of the handle substrate 13.

The forming of the donor substrate 10 may, for example, comprise, in this order, a step of bonding of a piezoelectric substrate onto a face of a handle substrate and a step of thinning of the piezoelectric substrate so as to form the donor layer. The forming of the donor substrate 10 may also comprise a step of heat treatment intended to strengthen the bonding interface formed between the donor layer and the handle substrate 13. The abovementioned forming of the donor substrate 10 is given only by way of example and is, therefore, not intended to limit the scope of the present disclosure.

The piezoelectric material forming the donor layer 12 may comprise at least one element selected from: LiTaO₃, LiNbO₃, LiAlO₃, BaTiO₃, PbZrTiO₃, KNbO₃, BaZrO₃, CaTiO₃, PbTiO₃, KTaO₃.

The handle substrate 13 may comprise any type of material, and more specifically a semiconductor material such as silicon, or an insulating material such as glass.

In one particular embodiment and as depicted in FIG. 2, the handle substrate may comprise a bulk substrate 13a on one face of which lies an intermediate layer 13b. More specifically, the intermediate layer 13b is in this particular embodiment interposed between the bulk substrate 13a and the donor layer 12.

The bulk substrate 13a may comprise any type of material, and more specifically a semiconductor material such as silicon, or an insulating material such as glass.

The intermediate layer 13b may comprise an insulating material, and more specifically a polymeric material, that ensures an adhesion function between the bulk substrate 13a and the donor layer 12.

The relative difference between the coefficients of thermal expansion of the materials forming respectively the handle substrate and the support substrate may be less than 10%. Use of such materials makes it possible to reduce the stresses likely to develop during the performance of a heat treatment in step d) as described hereinbelow.

Step a) is followed by a step b) shown in FIG. 1B.

More particularly, step b) comprises the forming of a weakened zone 14,

through the implantation of species in the donor layer 12. More specifically, the weakened zone extends in a plane parallel to the main face 11 and with the latter delimits a working layer 15.

“Weakened zone” is understood as meaning a zone along which a fracture wave is likely to propagate so as to cause detachment of the working layer 15 from the donor layer 12.

It is moreover understood, without it being necessary to specify this, that the implanted species are chosen so as to be able to cause, through thermal activation, firstly, a maturation of defects within the weakened zone and, secondly, the propagation of a fracture wave along the weakened zone.

The implantation of species may more particularly implement an ionic implantation and, more specifically, an implantation of hydrogen ions and/or of helium ions.

The implantation conditions, in terms of the dosing of the implanted species and the implantation energy, determine the thickness of the working layer 15. By way of example, and for a donor layer 12 made of LiTaO₃, dosing with hydrogen ions at a level of between 1^{E}16 at/cm² and 5^{E}17 at/cm², with an implantation energy of between 30 keV and 300 keV, permits the formation of a working layer 15 having a thickness of between 200 nm and 2000 nm.

The process according to the present disclosure also comprises the performance of a step c) (FIG. 1C).

Step c) comprises the joining of the donor substrate 10 and the support substrate 20 in such a way as to interpose the donor layer 12 between the support substrate 20 and the handle substrate 13.

Thus, and as illustrated in FIG. 1C, step c) comprising the joining comprises the bringing into contact of the main face 11 with a front face 21 of a support substrate 20.

The disclosure is not, however, limited to this aspect; it is possible to employ a step of forming of a layer of dielectric material on the donor layer and/or on the front face of the support substrate prior to step c).

In this connection, FIG. 5 depicts a donor substrate 10 that comprises a layer of dielectric material (for example, of silica), termed “first layer 17,” lying on the donor layer.

As an alternative or in addition, the layer of dielectric material may be formed on the front face of the support substrate 20. In this connection, FIG. 6 depicts a support substrate 20 that comprises a layer of dielectric material (for example, of silica), termed “second layer 22,” lying on the front face of the support substrate 20.

In such a case, the first layer 17 and/or the second layer 22 are to be found at the end of the performance of step c), interposed between the donor layer and the support substrate.

The joining step c) may comprise a molecular bonding that results, when the free faces of the donor and support substrates are brought into contact, in the propagation of a bonding wave and consequently in adhesion between said faces. The disclosure is not limited just to the implementation of a molecular bonding. It is in this connection possible to employ bonding by compression or by thermocompression, bonding by means of an adhesive layer.

Step c) is then followed by a step d) of heat treatment intended to initiate a fracture wave along the weakened zone so as to cause detachment of the working layer 15 and consequently to transfer the latter onto the front face 21 of the support substrate 20.

However, in order to prevent the development of cracks or of delamination of the donor layer at the interface formed between said donor layer 12 and the handle substrate 13, the heat treatment is performed in such a way that the initiation of the fracture wave occurs at the lowest possible temperature.

In this connection, the heat treatment comprises two phases respectively termed first phase and second phase.

FIG. 3 shows in graph form an example of heat treatment likely to be implemented during the performance of step d).

More particularly, FIG. 3 shows along the horizontal axis the time and along the vertical axis the temperature to which the assembly formed by the donor substrate 10 and the support substrate 20 is exposed, the first phase comprising, in this order: an increase in temperature A, a hold period at the first temperature B, and a decrease in temperature C to the second temperature.

The first phase (depicted in FIG. 1D) of a first duration dl, comprises an increase in temperature to a first temperature T1 and is designed firstly to allow a maturation of defects 16, generated by the species, in the weakened zone and secondly to prevent initiation of a fracture in said weakened zone.

“Maturation of defects” is understood as meaning the formation and growth of bubbles in the plane of the weakened zone. This maturation is activated by an input of thermal energy.

The second phase (depicted in FIG. 1E) of a second duration d2, comprises a hold period at a second temperature T2 lower than the first temperature T1 and is designed to initiate a fracture along the weakened zone and thus to transfer the working layer onto the front face.

It is understood, without it being necessary to specify this, that the second phase is performed in continuity with the first phase.

Step d) may more particularly be performed in a batch oven, under a controlled atmosphere and more specifically an inert atmosphere. The disclosure is not limited to the implementation of a batch oven. More particularly, a rapid thermal processing furnace may also be used.

The use of a two-phase heat treatment makes it possible to initiate a fracture wave, and consequently a transfer of the working layer 15 onto the support substrate 20, at a lower temperature than those currently envisaged in the state of the art.

The first phase may advantageously be preceded by a phase of strengthening the interface formed during the joining of the donor substrate and the support substrate. The strengthening phase is in this connection performed at a temperature, termed strengthening temperature Ts, lower than the first temperature.

It is understood, without it being necessary to specify this, that the first phase is adjusted according to the conditions of implantation of the species during the performance of step b).

More particularly, the conditions of the heat treatment, and more specifically the first temperature T1, the second temperature T2, the first duration d1 and the second duration d2, may be determined empirically.

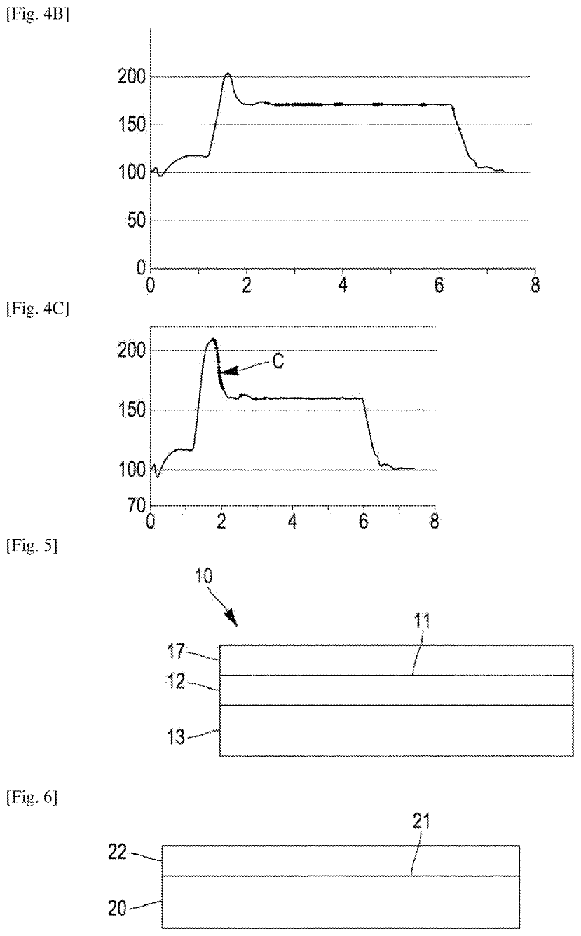

In this connection and by way of example, FIGS. 4A to 4C are graphical representations of different heat treatments to which batches of 25 assemblies obtained at the end of step c) were exposed. During the performance of each of these heat treatments, the inventors identified the moments of detection of the initiation of a fracture likely to occur within each of the assemblies.

Thus, FIG. 4A shows in graph form a heat treatment, termed first heat treatment, for which the first and second temperatures are respectively 200° C. and 160° C., while the first and second durations are, respectively, 7 minutes and 6 hours.

FIG. 4B shows in graph form a heat treatment, termed second heat treatment, that differs from the first heat treatment in that the second temperature and the second duration are, respectively, 170° C. and 4 hours.

FIG. 4C shows in graph form a heat treatment, termed third heat treatment, that differs from the first heat treatment in that the first and second durations are, respectively, 20 minutes and 4 hours.

During the performance of the first treatment, the inventors observed that 8 assemblies out of the 25 present in the heat-treatment oven did not undergo fracture.

The use of a second, higher temperature (170° C.) during performance of the second treatment (FIG. 4B) on the other hand permits the initiation of a fracture wave within each of the 25 assemblies in the second phase of said treatment. However, the initiation of a fracture wave in 2 of the 25 assemblies was observed only after the end of the hold period in the second phase. Under the prevailing conditions during the performance of this second annealing, it is not possible to confer the stability required for the process according to the present disclosure.

The use of a longer maturation period (first phase) during the performance of the third treatment resulted in the initiation of a fracture wave during the first phase (more specifically during the decrease in temperature C). A heat treatment of this nature does not permit stabilization of step d).

On the basis of these results, the inventors are of the view that the optimum heat-treatment parameters for the employed implantation conditions are as follows:
temperature T1=200° C.,
duration d1=15 minutes,
temperature T2=170° C.,
duration d2=4 hours.

The above principles thus make it possible to determine the optimum heat-treatment conditions for the performance of step d).

It is advantageous when the first temperature T1 is less than 300°° C., advantageously less than 250° C., even more advantageously less than 220° C.

It is always advantageous when the absolute difference between the first temperature T1 and the second temperature T2 is less than 40° C. and greater than 30° C. For example, the second temperature T2 is less than 180° C., advantageously less than 170° C.

It is advantageous when the second duration d2 is less than 6 hours, advantageously less than 4 hours.

The performance of the heat treatment in step d) according to the terms of the present disclosure makes it possible to decrease the temperature in the hold period during which the initiation of a fracture wave is likely to occur. This aspect makes it possible to reduce stresses at the interface formed between the donor layer and the handle substrate, and potentially in the intermediate layer if used.

In other words, the heat treatment, as used in the present disclosure, reduces the development of cracks and/or of delamination as described in the Background section of the present disclosure.

Needless to say, the disclosure is not limited to the embodiments described and implementation variants may be applied thereto without departing from the scope of the invention as defined by the claims.

1. A process of transferring a working layer onto a support substrate, the process comprising the following steps:
a) providing a donor substrate that comprises, starting from a main face, a donor layer formed from a piezoelectric material and a handle substrate, the donor layer disposed on one face of the handle substrate;
b) forming a weakened zone through implantation of species in the donor layer, the weakened zone being parallel to the main face, the weakened zone and the main face delimiting a working layer;
c) joining the support substrate with the donor substrate in such a way as to interpose the donor layer between the handle substrate and the support substrate; and
d) subjecting the joined support substrate and donor substrate to a heat treatment comprising, in this order, a first phase and a second phase; the first phase having a first duration and comprising an increase in temperature to a first temperature and is designed first, to allow a maturation of defects generated by the species in the weakened zone and, second, to prevent initiation of a fracture in the weakened zone; the second phase having a second duration and comprising a hold period at a second temperature lower than the first temperature, the second phase being designed to initiate a fracture along the weakened zone and thus to transfer the working layer onto the support substrate.

2. The process of claim 1, wherein step d) further comprises a strengthening phase preceding the first phase and performed at a strengthening temperature lower than the first temperature, the strengthening phase being intended to strengthen a bonding energy of an interface formed between the support substrate and the donor substrate during performance of step c).

3. The process of claim 2, wherein the first phase comprises, in this order: an increase in temperature, a hold period at the first temperature, and a decrease in temperature to the second temperature.

4. The process of claim 3, wherein the first phase is adjusted according to implantation conditions of the species during performance of step b).

5. The process of claim 1, wherein a relative difference between coefficients of thermal expansion of materials forming, respectively, the handle substrate and the support substrate is less than 10%.

6. The process of claim 1, wherein the handle substrate comprises a bulk substrate and an intermediate layer on one face of bulk substrate, the intermediate layer being interposed between the donor layer and the bulk substrate.

7. The process of claim 1, wherein the first temperature is less than 300° C.

8. The process of claim 1, wherein the second duration is less than 6 hours.

9. The process of claim 1, wherein the second temperature is less than 180° C.

10. The process of claim 1, wherein the species comprise at least one element selected from: hydrogen ions, helium ions.

11. The process of claim 1, wherein the piezoelectric material comprises at least one element selected from: LiTaO₃, LiNbO₃, LiAlO₃, BaTiO₃, PbZrTiO₃, KNbO₃, BaZrO₃, CaTiO₃, PbTiO₃, KTaO₃.

12. The process of claim 1, wherein step c) of joining is preceded by a step of forming of a layer of dielectric material on the donor layer and/or on a front face of the support substrate.

13. The process of claim 1, wherein step c) of joining comprises a molecular bonding.

14. The process of claim 6, wherein the intermediate layer comprises a polymeric material.

15. The process of claim 7, wherein the first temperature is less than 250° C.

16. The process of claim 15, wherein the first temperature is less than 220° C.

17. The process of claim 8, wherein the second duration is less than 4 hours.

18. The process of claim 9, wherein the second temperature is less than 170° C.

19. The process of claim 1, wherein the first phase comprises, in this order: an increase in temperature, a hold period at the first temperature, and a decrease in temperature to the second temperature.

20. The process of claim 1, wherein the first phase is adjusted according to implantation conditions of the species during performance of step b).
